(19) United States
(12) Patent Application Publication
(10) Pub. No.: US 2012/0134103 A1
(43) Pub. Date: May 31, 2012

(54) SERVER CABINET FOR SERVER SYSTEM

(75) Inventor: ZEU-CHIA TAN, Tu-Cheng (TW)

(73) Assignee: HON HAI PRECISION INDUSTRY CO., LTD., Tu-Cheng (TW)

(21) Appl. No.: 12/980,281

(22) Filed: Dec. 28, 2010

(30) Foreign Application Priority Data
Nov. 25, 2010 (TW) 99140681

(51) Int. Cl. G06F 1/20; H05K 5/02

(52) U.S. Cl. 361/679.46; 312/236

(57) ABSTRACT

A server cabinet adapted for receiving servers therein includes a top plate, a bottom plate opposite to the top plate, and a front side plate disposed between the top and bottom plates. The front side plate defines through holes therein. A total area of the through holes in an upper half portion of the front side plate adjacent to the top plate is different from a total area of the through holes in a lower half portion of the front side plate adjacent to the bottom plate.

### CROSS REFERENCE TO RELATED APPLICATIONS

This application is related to two co-pending applications respectively entitled “SERVER CABINET AND SERVER SYSTEM UTILIZING THE SAME” (attorney docket number US37112) and “SERVER CABINET AND SERVER SYSTEM USING THE SAME” (attorney docket number US34828), assigned to the same assignee of this application and filed on the same date as this application. The two related applications are incorporated herein by reference.

### BACKGROUND

1. Technical Field

The disclosure relates to server cabinets for use in server systems, and more particularly to a server cabinet facilitating heat dissipation.

2. Description of Related Art

Nowadays, numerous server systems are used for data storage and data operation. A server system generally includes a server cabinet, and a number of standard servers stacked in the server cabinet one on another along a height direction of the server cabinet. The servers generate considerable heat during operation, and may suffer damage if the heat is not efficiently removed.

What is needed, therefore, is a server cabinet for use in a server system which can overcome the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric, assembled view of a server cabinet of a server system in accordance with a first embodiment of the disclosure.

FIG. 2 is an exploded view of the server cabinet of FIG. 1.

FIG. 3 is an isometric, assembled view of the server cabinet of FIG. 1, seen from another viewpoint.

FIG. 4 is a cross sectional view of the server cabinet of FIG. 1, and showing an airflow generating device of the server system disposed at a top of the server cabinet.

FIG. 5 is essentially a cross sectional view of a server system in accordance with a second embodiment of the disclosure, wherein an airflow generating device is disposed at a bottom of a server cabinet.

### DETAILED DESCRIPTION

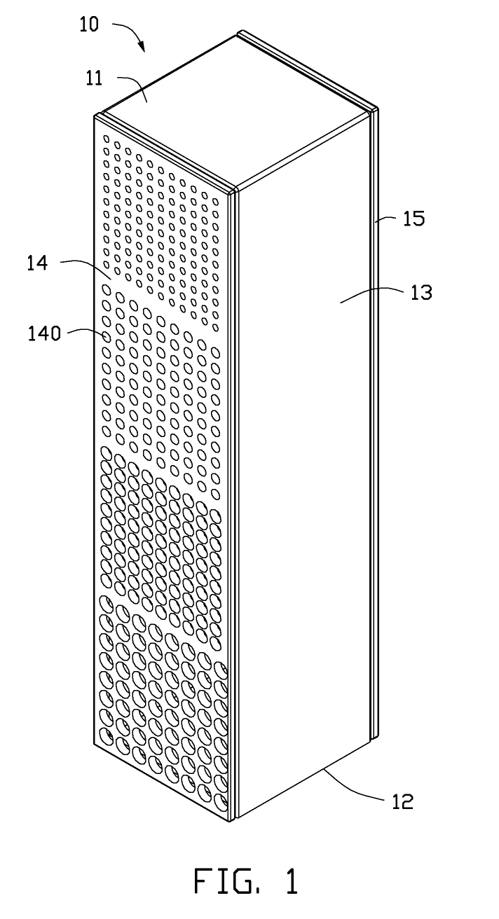

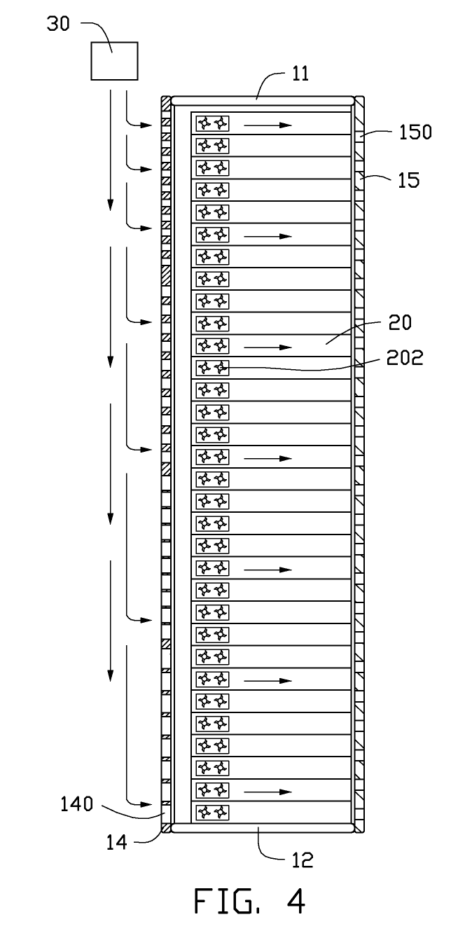

Referring to FIGS. 1 and 4, a server system in accordance with a first embodiment of the disclosure is shown. The server system includes a server cabinet 10, a plurality of standard servers 20 stacked in the server cabinet 10, and an airflow generating device 30 disposed near a top end of the server cabinet 10. The airflow generating device 30 is for generating airflow, and can be an air conditioner or a blower. The server system can be applied to, for example, a Container Data Center. The Container Data Center is a data center which is formed by mounting a plurality of server systems in a standard container.

The server cabinet 10 is substantially cuboid, and includes a top plate 11, a bottom plate 12 opposite to and parallel to the top plate 11, left and right side plates 13 connecting left and right edges of the top and bottom plates 11, 12 respectively, a front side plate 14 disposed at a front side of the top and bottom plates 11, 12, and a rear side plate 15 disposed at a rear side of the top and bottom plates 11, 12. The top and bottom plates 11, 12, the left and right side plates 13, and the front and rear plates 14, 15 cooperatively form a receiving space 16.

The front side plate 14 pivotedly connects one of the left and right side plates 13. The front side plate 14 defines a plurality of through holes 140. The through holes 140 are arranged in four matrixes, and the matrixes are arranged in a line along a height direction of the front side plate 14. The through holes 140 in each matrix have the same diameter, and the through holes 140 in any two given matrixes have different diameters. A total area of the through holes 140 in an upper half portion of the front side plate 14 adjacent to the top plate 11 is different from a total area of the through holes 140 in a lower half portion of the front side plate 14 adjacent to the bottom plate 12. The diameters of the through holes 140 of the four matrixes gradually increase from the topmost matrix adjacent to the airflow generating device 30 to the bottommost matrix farthest away from the airflow generating device 30. Thus in this embodiment, with the airflow generating device 30 adjacent to the top end of the front side plate 14, the diameter of the through holes 140 of the topmost matrix adjacent to the airflow generating device 30 is smaller than that of the through holes 140 of the bottommost matrix farthest away from the airflow generating device 30. Accordingly, the total area of the through holes 140 in the top portion of the front side plate 14 is smaller than the total area of the through holes 140 in the bottom portion of the front side plate 14.

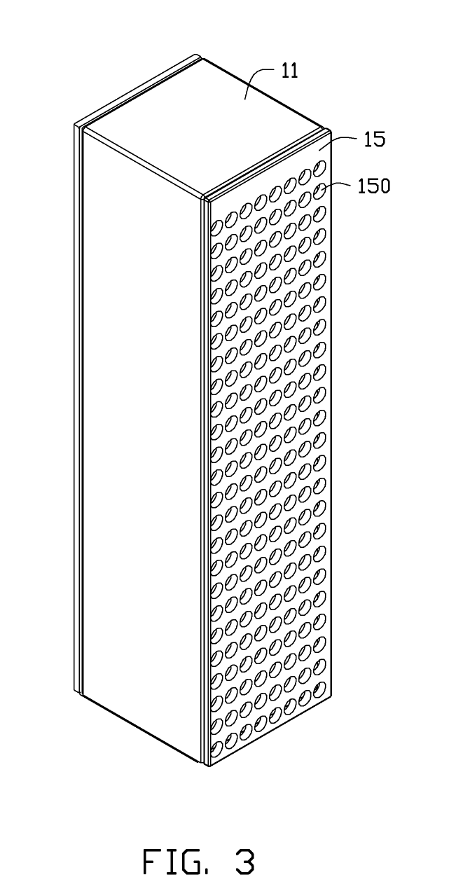

Also referring to FIG. 3, the rear side plate 15 pivotedly connects one of the left and right side plates 13. The rear side plate 15 defines a plurality of through holes 150 arranged in a matrix. The through holes 150 have the same diameter.

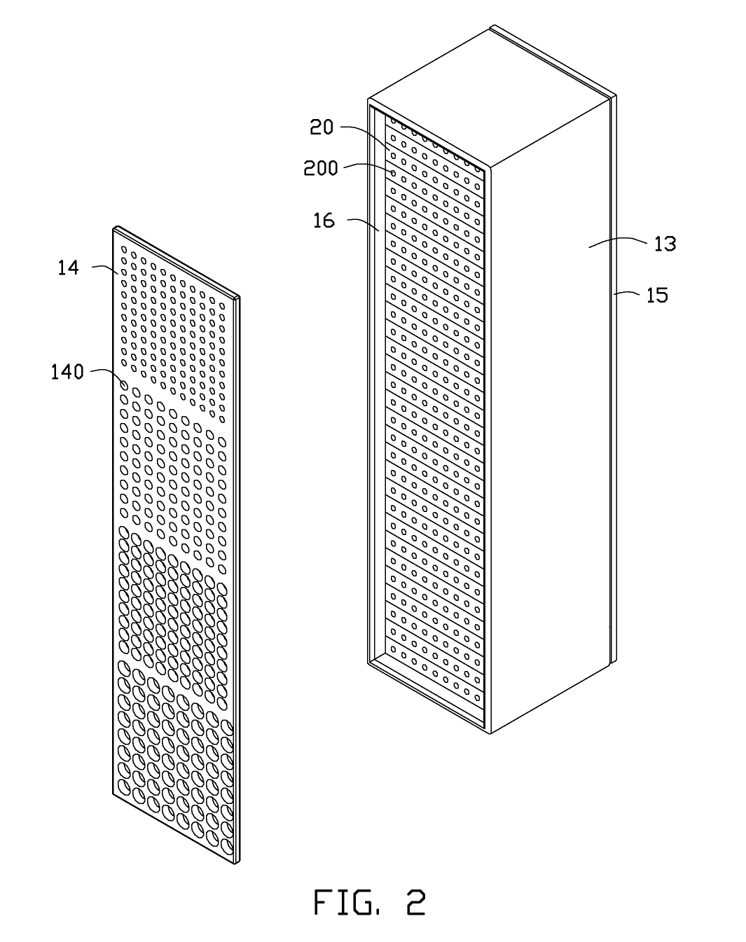

Also referring to FIG. 2, the servers 20 are received in the receiving space 16 of the server cabinet 10 and stacked one on another. Each server 20 defines a plurality of through holes 200 respectively in front and rear sides thereof, corresponding to the through holes 140 of the front side plate 14 and the through holes 150 of the rear side plate 15. A plurality of fans 202 for generating intake airflow are disposed in each server 20.

In use, cold (or cooler) airflow generated by the airflow generating device 30 blows from the top of the server cabinet 10 to the bottom of the server cabinet 10. The air flows through the through holes 140 of the front side plate 14 into the server cabinet 10. The fans 202 suck the airflow through the through holes 200 in the front sides of the servers 20 and exhaust hot airflow out of the servers 20 via the through holes 200 in the rear sides of the servers 20, to thereby dissipate heat from the servers 20. The hot air outside the servers 20 then flows out from the server cabinet 10 via the through holes 150 of the rear side plate 15.

Since the airflow generating device 30 is disposed near the top end of the front side plate 14 of the server cabinet 10, much more airflow can directly blow to the top portion of the server cabinet 10. In addition, since diameters of the through holes 140 of the four matrixes gradually increase from the portion of the front side plate 14 adjacent to the airflow generating device 30 to the portion of the front side plate 14 farthest away from the airflow generating device 30, and since the total area of the through holes 140 in the portion of the front side plate 14 adjacent to the airflow generating device 30 is less than the total area of the through holes 140 in the portion of the front side plate 14 away from the airflow generating device 30, a portion of airflow generated by the airflow generating device 30 and flowing through the through holes 140 adjacent to the airflow generating device 30 is attenuated, and a portion of the airflow generated by the airflow generating device 30 and flowing through the through holes 140 away from the airflow generating device 30 is amplified. Thus, the airflow generated by the airflow generating device 30 can flow toward the servers 20 in the server cabinet 10 more evenly. In particular, the servers 20 away from the airflow generating device 30 can receive more airflow than would otherwise be the case. This improves a heat dissipation efficiency of the server system.

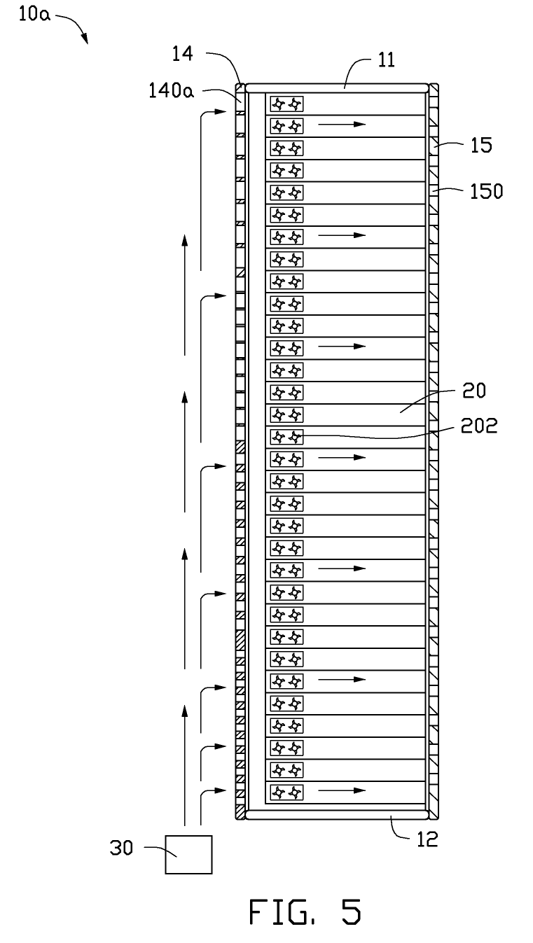

Referring to FIG. 5, a server system in accordance with a second embodiment of the disclosure is shown. The server system includes a server cabinet 10a, a plurality of standard servers 20 stacked in the server cabinet 10a, and an airflow generating device 30. The differences between the server system of the second embodiment and the server system of the first embodiment are as follows. The airflow generating device 30 is disposed near a bottom end of a front side plate 14 of the server cabinet 10a. Diameters of four matrixes of through holes 140a of the front side plate 14 gradually increase from a bottommost portion matrix adjacent to the airflow generating device 30 to a topmost matrix farthest away from the airflow generating device 30. A total area of the through holes 140a in a bottom portion (i.e., half) of the front side plate 14 adjacent to the airflow generating device 30 is less than a total area of the through holes 140a in the top portion (i.e., half) of the front side plate 14 away from the airflow generating device 30.

It is believed that the disclosure and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A server cabinet adapted for receiving a plurality of servers therein, the server cabinet comprising:
a top plate and a bottom plate parallel to the top plate; and
a front side plate disposed between the top and bottom plates, the front side plate defining a plurality of through holes therein, a total area of the through holes in an upper half portion of the front side plate being different from a total area of the through holes in a lower half portion of the front side plate.

2. The server cabinet of claim 1, wherein the through holes are arranged in a plurality of matrixes along a height direction of the front side plate, the through holes in each matrix having the same diameter, the through holes in different matrixes having different sizes of diameters.

3. The server cabinet of claim 2, wherein the diameter of each through hole in the upper half portion of the front side plate adjacent to the top plate is smaller than the diameter of each through hole in the lower half portion of the front side plate adjacent to the bottom plate.

4. The server cabinet of claim 2, wherein the diameters of the through holes gradually increase from the upper half portion of the front side plate adjacent to the top plate to the lower half portion of the front side plate adjacent to the bottom plate.

5. The server cabinet of claim 1, further comprising a rear side plate disposed at a rear side of the top and bottom plates and defining a plurality of through holes therein, and a left side plate and a right side plate connecting with the top and bottom plates respectively, the front plate being disposed at a front side of the top and bottom plates.

6. The server cabinet of claim 5, wherein the through holes in the rear side plate has a same diameter.

7. The server cabinet of claim 5, wherein the rear side plate pivotedly connects one of the left and right side plates.

8. The server cabinet of claim 1, wherein the front side plate pivotedly connects one of the left and right side plates.

9. A server system comprising:
a server cabinet comprising:
a top plate and a bottom plate opposite to the top plate; and
a front side plate disposed between the top and bottom plates, the front side plate defining a plurality of through holes therein, a total area of the through holes in an upper half portion of the front side plate being different from a total area of the through holes in a lower half portion of the front side plate;
a plurality of servers received in the server cabinet and stacked one on another; and
an airflow generating device configured for generating airflow, the airflow generating device disposed near one of a top end and a bottom end of the front side plate of the server cabinet.

10. The server system of claim 9, wherein the through holes are arranged in a plurality of matrixes along a height direction of the front side plate, the through holes in each matrix having the same diameter, the through holes in different matrixes having different sizes of diameters.

11. The server system of claim 10, wherein the diameter of each through hole in the upper half portion of the front side plate adjacent to the top plate is smaller than the diameter of each through hole in the lower half portion of the front side plate adjacent to the bottom plate, the airflow generating device being disposed near a top end of the front side plate of the server cabinet.

12. The server system of claim 10, wherein the diameters of the through holes gradually increase from the upper half portion of the front side plate adjacent to the top plate to the lower half portion of the front side plate adjacent to the bottom plate, the airflow generating device being disposed near a top end of the front side plate of the server cabinet.

13. The server system of claim 9, further comprising a rear side plate disposed at a rear side of the top and bottom plates and defining a plurality of through holes therein, and a left side plate and a right side plate connecting with the top and bottom plates respectively, the front plate being disposed at a front side of the top and bottom plates.

14. The server system of claim 13, wherein the through holes in the rear side plate has a same diameter.

15. The server system of claim 13, wherein the rear side plate pivotedly connects one of the left and right side plates.

16. The server system of claim 13, wherein at least one fan for absorbing airflow is disposed in each of the servers.

17. The server system of claim 9, wherein the front side plate pivotedly connects one of the left and right side plates.

18. The server system of claim 9, wherein at least one fan for absorbing airflow is disposed in each of the servers.

19. The server system of claim 18, wherein each server defines a plurality of through holes respectively in front and rear sides thereof.

20. The server system of claim 9, wherein the airflow generating device is an air conditioner.
